(19) United States
(12) Patent Application Publication
(10) Pub. No.: US 2026/0229847 A1
(43) Pub. Date: Aug. 6, 2026

(54) SURFACE-EMITTING LASER AND SURFACE-EMITTING LASER ARRAY

(71) Applicant: Sony Group Corporation, Tokyo (JP)

(72) Inventors: Mikihiro YOKOZEKI, Kanagawa (JP); Hiroshi NAKAJIMA, Kanagawa (JP); Masayuki TANAKA, Kanagawa (JP); Tomomasa WATANABE, Kanagawa (JP); Michinori SHIOMI, Kanagawa (JP)

(21) Appl. No.: 19/152,312

(22) PCT Filed: Jan. 19, 2024
(86) PCT No.: PCT/JP2024/001400

§ 371 Date: Jul. 30, 2025

(30) Foreign Application Priority Data
Mar. 13, 2023 (JP) 2023-039022

(51) Int. Cl. H01S 5/183; H01S 5/34

(52) U.S. Cl. CPC H01S 5/18361; H01S 5/3416

(57) ABSTRACT

A surface-emitting laser according to one embodiment of the present disclosure includes a first DBR layer, a second DBR layer, an active layer, a first spacer layer, a second spacer layer, and a tunnel junction layer. The active layer is disposed between the first DBR layer and the second DBR layer. The first spacer layer is disposed between the active layer and the first DBR layer. The second spacer layer is disposed between the active layer and the second DBR layer. The tunnel junction layer is disposed between the active layer and the second DBR layer, and is surrounded by the second spacer layer. The second spacer layer and a portion of a side surface of the tunnel junction layer have an air gap therebetween.

### TECHNICAL FIELD

The present disclosure relates to a surface-emitting laser and a surface-emitting laser array.

### BACKGROUND ART

A surface-emitting laser is disclosed in Patent Literature 1, for example.

### CITATION LIST

### Patent Literature

Patent Literature 1: Japanese Unexamined Patent Application Publication No. 2006-508550

### SUMMARY OF THE INVENTION

A surface-emitting laser described in Patent Literature 1 uses a tunnel junction structure that confines electric currents and light. There is a concern that use of this tunnel junction structure leads to crystal faults, depending on a material to be selected. It is desirable to provide a surface-emitting laser and a surface-emitting laser array that make it difficult to cause a crystal fault even in a case where the tunnel junction structure is used.

A surface-emitting laser according to one embodiment of the present disclosure includes a first DBR layer, a second DBR layer, an active layer, a first spacer layer, a second spacer layer, and a tunnel junction layer. The active layer is disposed between the first DBR layer and the second DBR layer. The first spacer layer is disposed between the active layer and the first DBR layer. The second spacer layer is disposed between the active layer and the second DBR layer. The tunnel junction layer is disposed between the active layer and the second DBR layer, and is surrounded by the second spacer layer. The second spacer layer and a portion of a side surface of the tunnel junction layer have an air gap therebetween.

### BRIEF DESCRIPTION OF THE DRAWINGS

FIG. 1 is a diagram illustrating a cross-sectional configuration example of a surface-emitting laser according to a first embodiment of the present disclosure.

FIG. 2 is a diagram illustrating a plan configuration example of the surface-emitting laser of FIG. 1.

FIG. 3 is an enlarged diagram illustrating a cross-sectional configuration example of a tunnel junction layer and neighborhood thereof in FIG. 1.

FIG. 4 is a diagram illustrating a cross-sectional configuration example along line A-A in FIG. 3.

FIG. 5A is a diagram illustrating an example of a manufacturing method of the surface-emitting laser of FIG. 1.

FIG. 5B is a diagram illustrating an example of a manufacturing process subsequent to FIG. 5A.

FIG. 5C is a diagram illustrating an example of a manufacturing process subsequent to FIG. 5B.

FIG. 5D is a diagram illustrating an example of a manufacturing process subsequent to FIG. 5C.

FIG. 5E is a diagram illustrating an example of a manufacturing process subsequent to FIG. 5D.

FIG. 6 is a diagram illustrating a modification example of a cross-sectional configuration of FIG. 4.

FIG. 7 is a diagram illustrating a modification example of the cross-sectional configuration of the surface-emitting laser of FIG. 1.

FIG. 8 is a diagram illustrating a modification example of the cross-sectional configuration of the surface-emitting laser of FIG. 1.

FIG. 9 is an enlarged diagram illustrating a modification example of the cross-sectional configuration of the tunnel junction layer and neighborhood thereof in FIG. 1, FIG. 7, and FIG. 8.

FIG. 10 is an enlarged diagram illustrating a modification example of the cross-sectional configuration of the tunnel junction layer and neighborhood thereof in FIG. 1, FIG. 7, and FIG. 8.

FIG. 11 is an enlarged diagram illustrating a modification example of the cross-sectional configuration of FIG. 3.

FIG. 12 is an enlarged diagram illustrating a modification example of the cross-sectional configuration of FIG. 9

FIG. 13 is an enlarged diagram illustrating a modification example of the cross-sectional configuration of FIG. 10.

FIG. 14 is a diagram illustrating a modification example of the cross-sectional configuration of FIG. 1.

FIG. 15 is a diagram illustrating a cross-sectional configuration example of a surface-emitting laser according to a second embodiment of the present disclosure.

FIG. 16 is a diagram illustrating a plan configuration example of the surface-emitting laser of FIG. 15.

FIG. 17 is a diagram illustrating a modification example of the cross-sectional configuration of the surface-emitting laser of FIG. 15.

FIG. 18 is a diagram illustrating a cross-sectional configuration example of a surface-emitting laser according to a third embodiment of the present disclosure.

FIG. 19 is a diagram illustrating a modification example of the cross-sectional configuration of the surface-emitting laser of FIG. 18.

FIG. 20 is a diagram illustrating a modification example of the cross-sectional configuration of the surface-emitting laser of FIG. 18.

FIG. 21 is a diagram illustrating a modification example of the cross-sectional configuration of the surface-emitting laser of FIG. 18.

### MODES FOR CARRYING OUT THE INVENTION

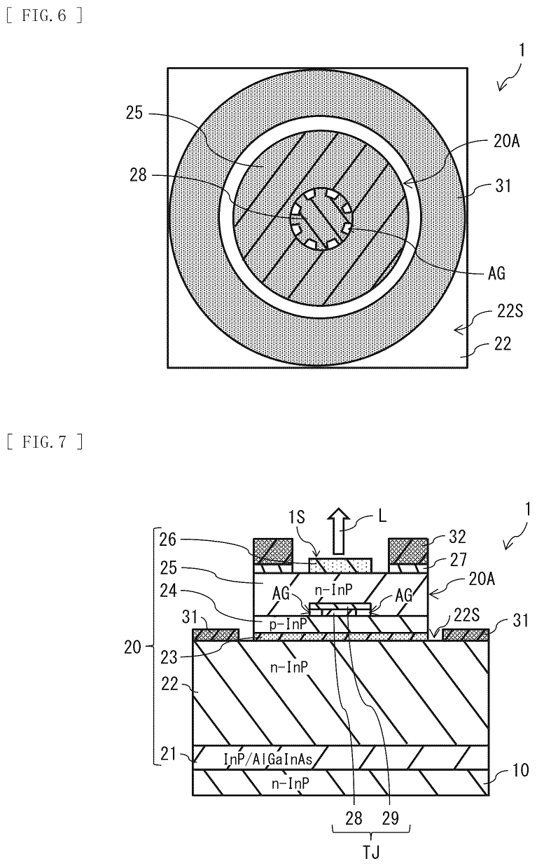

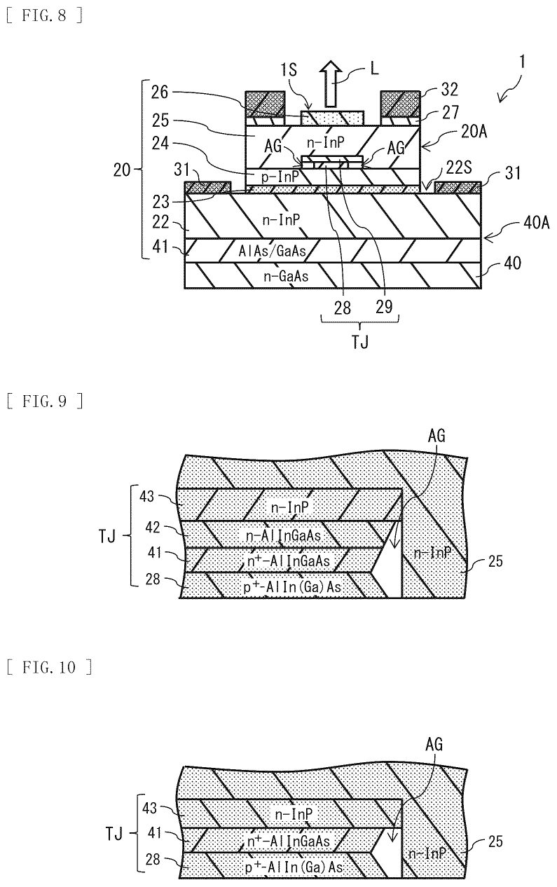

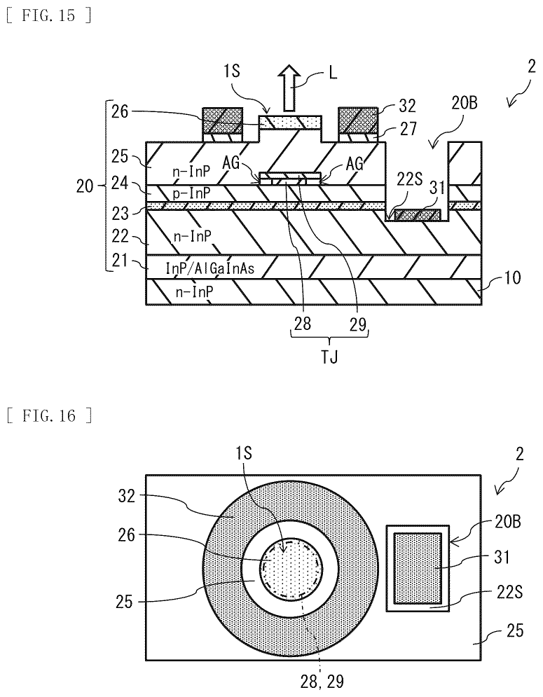

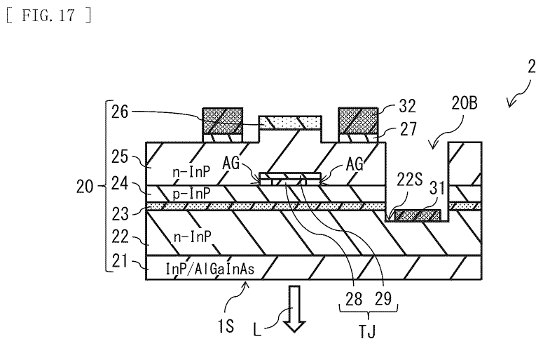

Hereinafter, an embodiment for practicing the present disclosure is described in detail with reference to the drawings. The following description is a specific example of the present disclosure, and the present disclosure is not limited to the following embodiments. Moreover, the present disclosure does not limit the disposition, dimensions, dimension ratios, and the like of respective components illustrated in the drawings thereto. It is to be noted that description is given in the following order.
0. Background
1. First Embodiment
   Example in which an air gap is provided on a side surface of a tunnel junction layer (FIG. 1 to FIG. 5E)
2. Modification Examples of First Embodiment
   Modification Example A: Example in which a plurality of air gaps is provided (FIG. 6)
   Modification Example B: Example of a long cavity (FIG. 7)
   Modification Example C: Example in which a lower DBR layer is made of a GaAs-based semiconductor
   Modification Example D: Variations of a tunnel junction layer (FIG. 9 and FIG. 10)
   Modification Example E: Example in which an amorphous oxide film is provided (FIG. 11 to FIG. 13)
   Modification Example F: Surface-emitting laser of a back emitting type (FIG. 14)
3. Second Embodiment
   Example in which a lower electrode is provided on a bottom surface of a groove section (FIG. 15 and FIG. 16)
4. Modification Example of Second Embodiment
   Modification Example G: Surface-emitting laser of the back emitting type (FIG. 17)
5. Third Embodiment
   Example in which a multi-emitter is provided (FIG. 18 to FIG. 21)

### 0. Background

An InP material has been used for a long time as a material for optical communication laser elements, because the InP material is a light emitting material in 1.31 μm and 1.5 μm bands that are low loss regions of optical fibers. Although a device based on this InP material has superior light emitting characteristics, the device has a characteristic that laser characteristics widely vary with temperature. Reasons for this are that a carrier readily overflows due to an intrinsic characteristic of a material, and that a thermal resistance of a mixed crystal material necessary for device structure designing, such as AlInGaAs or InGaAsP and the like, is 10 or more times higher than that of an InP layer, resulting in poor thermal dissipation.

For an active layer material, there is a report that a characteristic temperature has improved by applying AlInGaAs active layer of an As-based material or a QD active layer (quantum dot: Quantum Dots) having a relatively large ΔEc to suppress a carrier overflow. In the case of the AlInGaAs active layer, materials with a relatively good characteristic temperature of 70K to 80K have been commercialized. In contrast, in the case of an InP-based material, in order to adjust a light confinement rate, it is difficult to make a device without using the mixed crystal-based materials such as InGaAsP or AlInGaAs in designing the device structure. In general, a temperature rise ΔTj in the active layer is expressed as ΔTj=IV·Rth (thermal resistance). That is, it is seen that a high thermal resistance is a major cause for the temperature rise in the active layer.

In an optical communication device, wavelengths have to be strictly controlled because the optical communication device is used in WDM (wavelength division multiplexing; Wavelength Division Multiplexing), and the like. For this reason, temperature control by a thermal regulator is common, and improvement in temperature characteristics was desired, but not indispensable.

Meanwhile, recently, as short-range communications, in particular, communications for data centers, 850 nm band VCSELs (vertical cavity surface-emitting laser: Vertical Cavity Surface Emitting Laser) on GaAS substrates have been used. A GaAs-based material is a material suitable for making VCSELs. Major reasons for this are that it is possible to fabricate an AlAs/GaAs DBR (black reflecting mirror: Distributed Bragg Reflector) having a relatively large refractive index difference in a lattice matching system, that the thermal dissipation is good, or that use of an AlAs oxide narrowing layer technique is possible as a method of confining the electric currents and the light, the AlAs oxide narrowing layer being an AlAs layer oxidized from a mesa side surface. Advantages of VCSELs over EEL are that VCSELs are small and highly reliable, and that arrangement in two dimensions with good compatibility with Si circuits is possible.

In addition, recently, demands for VCSELs have been growing more for 3D sensing applications than for the optical communications. In particular, face authentication for smart phones has been increasing. In addition, a possibility of using VCSELs in LiDAR systems for self-supported vehicles is under study, and it is expected that a VCSEL sensing market will further expand.

For InP-based devices, commercialization and research and development of VCSEL devices are also under way. For example, VERTILAS GmbH makes reflecting mirrors from epitaxial DBR and dielectric DBR plus metal, and improves the thermal dissipation and makes characteristics better by reducing a number of pairs of dielectrics. In this structure, the metal provided to reduce the number of dielectric pairs makes it possible not only to increase a reflective index, but also to improve the thermal dissipation. However, because a thermal conductivity of the dielectric DBR is low, further improvement in thermal dissipation is desired. Additionally, BeamExpress, Inc. forms reflecting mirrors by bonding AlAs/GaAs-based DBR substrates above and below an InP-based active layer, thereby realizing devices with good thermal dissipation. In this structure, the thermal dissipation is excellent and it is possible to obtain good characteristics. However, excellent surface flatness is necessary to directly bond InP and the GaAs substrate, thus making mass production very difficult.

In InP-based VCSELs, it is not possible to use AlAs layers due to lattice mismatch. For this reason, it is difficult to use an AlOx narrow layer that is widely used in GaAs-based VSCELs. However, because it is possible to perform regrowing relatively easily compared to a GaAs system, a buried tunnel junction (BTJ: Buried Tunnel Junction) structure where a tunnel junction layer is regrown after being etched, and then buried has become widely used. For example, the structure of VERTILAS GmbH combines a BTJ and the epitaxial DBR, and some of the structure have been commercialized.

This BTJ structure is a very excellent structure in that it is possible to achieve both current constriction and light confinement. However, in order to form a low-resistance TJ layer, the As-based materials are often used in one or both of an n-layer and a p-layer. A reason for this is that although a narrow bandgap is desired to reduce resistance of the TJ, an AlInGaAs layer is advantageous in that it is possible to narrow the bandgap while lattice-matching. In addition, C is often used as a p-type dopant in MOCVD that has an advantage that inclusion of Al improves an efficiency of taking in C. However, there is a concern in regrowth on a substrate where a TJ mesa is formed that the As-based material surface appears on the side surface, and thus crystal faults occur depending on conditions of film formation. Moreover, there is a concern that use of Al-based materials makes it difficult to remove an oxide layer completely, and faults occur from a regrowth interface portion thereof. There is another concern that it is not possible to control light confinement freely because the TJ layer is also subject to material constraints due to tunneling characteristics.

The present disclosure aims to clear these concerns.

### 1. First Embodiment

### Configuration

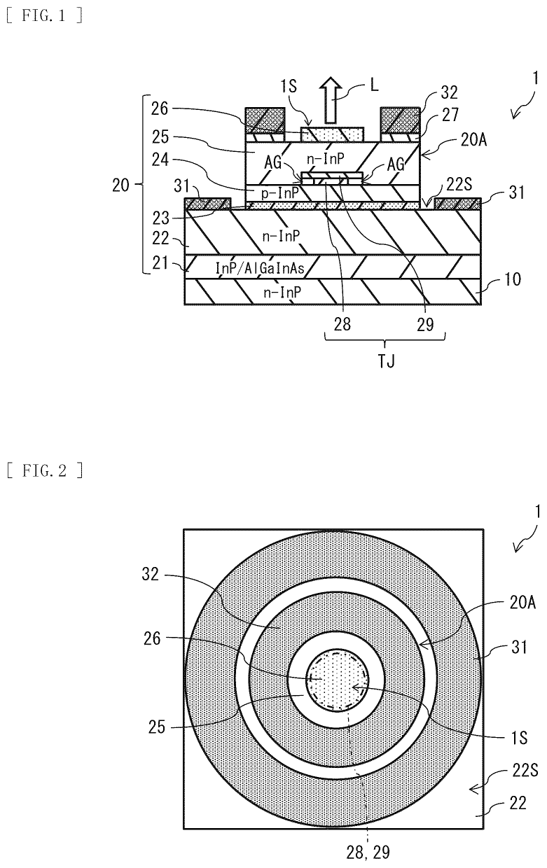

A description will be given of a surface-emitting laser 1 according to a first embodiment of the present disclosure. FIG. 1 illustrates a cross-sectional configuration example of the surface-emitting laser 1. FIG. 2 illustrates a plan configuration example of the surface-emitting laser 1.

The surface-emitting laser 1 includes an emitter 20 on a substrate 10. The substrate 10 is a crystal growth substrate used to cause epitaxial crystal growth of the emitter 20 (for example, a semiconductor DBR layer 21 and a spacer layer 22 and the like, to be described below). It is possible to omit the substrate 10 in the surface-emitting laser 1.

The emitter includes the semiconductor DBR layer 21, a dielectric DBR layer 26, and a cavity layer disposed between the semiconductor DBR layer 21 and the dielectric DBR layer 26, and is a so-called vertical cavity. The cavity layer is designed in accordance with an oscillation wavelength λ0 or application. The cavity layer has, for example, the spacer layer 22 disposed between an active layer 23 and the semiconductor DBR layer 21, spacer layers 24 and 25 disposed between the active layer 23 and the dielectric DBR layer 26, and a tunnel junction layer TJ disposed between the active layer 23 and the dielectric DBR layer 26.

The spacer layer 24 is disposed on the active layer 23 side, and the spacer layer 25 is disposed on the dielectric DBR layer 26 side. The tunnel junction layer TJ is surrounded by the spacer layers 24 and 25. The spacer layer 24 is in contact with a bottom surface of the tunnel junction layer TJ, and the spacer layer 25 is in contact with a top surface of the tunnel junction layer TJ and a portion of a side surface of the tunnel junction layer TJ. An air gap AG exists between the portion of the side surface of the tunnel junction layer TJ and the spacer layer 25.

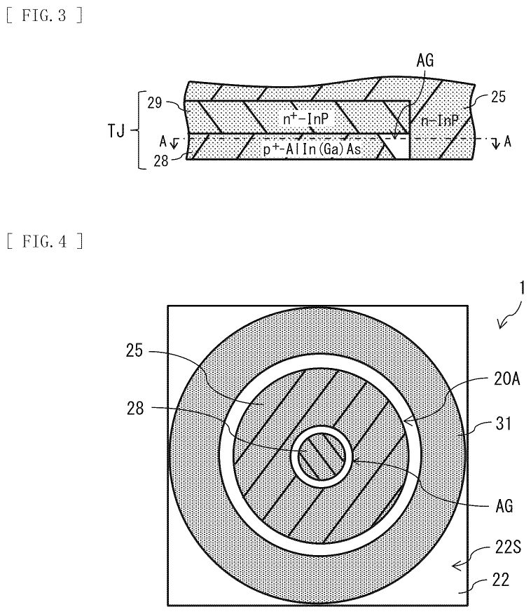

As illustrated in FIG. 1, for example, the tunnel junction layer TJ is configured by stacking a high-concentration p-layer 28 and a high-concentration n-layer 29 in this order from the active layer 23 side. The spacer layer 24 is in contact with a bottom surface of the high-concentration p-layer 28, and the air gap AG exists between a side surface of the high-concentration p-layer 28 and the spacer layer 25, as illustrated in FIG. 3 and FIG. 4, for example. The air gap AG has an annular shape surrounding the entire side surface of the high-concentration p-layer 28. That is, the spacer layer 25 is not in contact with the side surface of the high-concentration p-layer 28. The high-concentration p-layer 28 is in contact with a bottom surface of the high-concentration n-layer 29, and the spacer layer 25 is in contact with a top surface and a side surface of the high-concentration n-layer 29. The air gap AG has a size in a vertical direction that is equal to a thickness of the high-concentration p-layer 28. The air gap AG has a size in a horizontal direction (lamination in-plane direction) that is adjustable according to the conditions of film formation.

The tunnel junction layer TJ forms a current constriction structure by a tunnel junction. In the tunnel junction layer TJ, a conduction band of the high-concentration p-layer 28 and a valence band of the high-concentration n-layer 29 are close to each other at a boundary between the high-concentration p-layer 28 and the high-concentration n-layer 29, and a tunnel junction is formed by the high-concentration p-layer 28 and the high-concentration n-layer 29. As a result of this, in the tunnel junction layer TJ, an electric current flows from the high-concentration n-layer 29 to the high-concentration p-layer 28.

The surface-emitting laser 1 is configured so that laser light L having the oscillation wavelength λ0 is output from the dielectric DBR layer 26 side. Specifically, in the emitter 20, a number of pairs or the reflective index of a reflecting mirror on the semiconductor DBR layer 21 side and the number of pairs or the reflective index of a reflecting mirror on the dielectric DBR layer 26 side are configured so that the laser light L having the oscillation wavelength λ0 is output from the dielectric DBR layer 26 side. Therefore, the surface-emitting laser 1 is a top emitting type laser that outputs the laser light L from a light emitting surface IS provided on the dielectric DBR layer 26 side.

In the emitter 20, at least the active layer 23, the spacer layer 24, the tunnel junction layer, the spacer layer 25, and the dielectric DBR layer 26 constitute a columnar mesa part 20A that extends in a normal direction of the substrate 10. FIG. 1 illustrates an example in which the mesa part 20A includes the active layer 23, the spacer layer 24, the tunnel junction layer, the spacer layer 25, and the dielectric DBR layer 26. The mesa part 20A has, for example, a circular shape in plan view. The semiconductor DBR layer 21 is provided in a region on the substrate 10 side in a positional relationship with the mesa part 20A.

The tunnel junction layer TJ is provided at a central portion of the mesa part 20A in plan view. The tunnel junction layer TJ has, for example, a circular shape in plan view. The tunnel junction layer TJ is provided at a position opposite to the substrate 10 (that is, the light emitting surface 1S side) in a positional relationship with the active layer 23. The dielectric DBR layer 26 is in contact with a top surface of the spacer layer 25 and is in contact with a central portion of the spacer layer 25 in plan view.

As illustrated in FIG. 1 and FIG. 2, for example, the surface-emitting laser 1 further includes a contact layer 27 and an electrode layer 32 as a top electrode on an upper portion of the mesa part 20A. The contact layer 27 is in contact with the spacer layer 25 and the electrode layer 32. As illustrated in FIG. 1, for example, the contact layer 27 is in contact with an outer edge portion of a top surface of the mesa part 20A, and has an annular shape surrounding the central portion of the spacer layer 25 (the dielectric DBR layer 26) in plan view. The contact layer 27 is a layer for making the spacer layer 25 and the electrode layer 32 in ohmic contact with each other. The electrode layer 32 is in contact with the contact layer 27, and is electrically coupled to the spacer layer 25 through the contact layer 27 and further not through the dielectric DBR layer 26. As illustrated in FIG. 1 and FIG. 2, for example, the electrode layer 32 has an annular shape surrounding the central portion of the spacer layer 25 (the dielectric DBR layer 26) in plan view.

As illustrated in FIG. 1, for example, the surface-emitting laser 1 further includes an electrode layer 31 as a lower electrode at an area corresponding to a foot of the mesa part 20A. As illustrated in FIG. 1 and FIG. 2, for example, a portion of the spacer layer 22 is exposed at the area corresponding to the foot of the mesa part 20A. Hereinafter, the area of the spacer layer 22 corresponding to the foot of the mesa part 20A is referred to as an exposed surface 22S. The exposed surface 22S is a flat surface. The exposed surface 22S is a flat surface parallel to, for example, a stacked surface in the semiconductor DBR layer 21, and is disposed, for example, in plane with an interface between the spacer layer 22 and the active layer 23. The electrode layer 31 is in contact with a portion of the exposed surface 22S. The electrode layer 31 is electrically coupled to the spacer layer 22 not through the semiconductor DBR layer 21. Therefore, in the surface-emitting laser 1, a current path formed by the electrode layer 31 and the electrode layer 32 is provided not through the semiconductor DBR layer 21 and the dielectric DBR layer 26.

Next, a description will be given of materials of respective components that constitute the surface-emitting laser 1.

The substrate 10 is an n-type InP substrate. The n-type InP substrate includes, for example, silicon (Si) as an n-type impurity.

The semiconductor DBR layer 21 is, for example, an undoped InP-based semiconductor DBR layer. The semiconductor DBR layer 21 is configured by alternately stacking low-refractive index semiconductor layers including undoped InP and high-refractive index semiconductor layers including undoped AlInGaAs. The low-refractive index semiconductor layers and the high-refractive index semiconductor layers each have an optical thickness of, for example, λ0×1/4. The semiconductor DBR layer 21 may include, for example, an n-type impurity.

The spacer layers 22, 24, and 25 include an InP-based semiconductor, for example. The spacer layer 22 includes n-type InP, for example. The n-type InP includes, for example, silicon (Si) and the like, as the n-type impurity. An n-type impurity concentration of the spacer layer 22 is, for example, 3×10¹⁷ to 1×10¹⁸ cm⁻³. The spacer layer 24 includes p-type InP, for example. The p-type InP includes carbon (C), zinc (Zn), magnesium (Mg), beryllium (Be), and the like, as a p-type impurity. A p-type impurity concentration of the spacer layer 24 is, for example, 3×10¹⁷ to 1×10¹⁸ cm⁻³. The spacer layer 25 includes the n-type InP, for example. The n-type InP includes, for example, silicon (Si) and the like, as the n-type impurity. The n-type impurity concentration is, for example, 5×10¹⁷ to 2×10¹⁸ cm⁻³.

The dielectric DBR layer 26 is configured by alternately stacking low-refractive index dielectric layers formed of a first dielectric material and high-refractive index dielectric layers formed of a second dielectric material. The low-refractive index dielectric layers and the high-refractive index dielectric layers each have the optical thickness of, for example, λ0×1/4. The low-refractive index dielectric layer is formed of SiO2, for example. The high-refractive index dielectric layer is formed of Ta₂O₅, for example. A material for the dielectric DBR layer 26 is not limited to the above-mentioned dielectric materials.

The contact layer 27 includes, for example, n-type InGaAs including the n-type impurity having a higher concentration than the n-type impurity concentration included in the spacer layer 25. The n-type InGaAs includes, for example, the same impurity as the n-type impurity included in the spacer layer 25. The electrode layer 31 has a structure in which Ti, Pt, and Au are stacked in this order from side of an inner surface of a recess 22A of the spacer layer 22. Ti, Pt, and Au are formed by a sputtering method, for example. The electrode layer 32 includes Ti, Pt, and Au, for example.

The high-concentration p-layer 28 includes Al atoms. The high-concentration p-layer 28 and the high-concentration n-layer 29 include respective materials having mutually different group V atoms. The high-concentration p-layer 28 includes, for example, As as a group V atom. The high-concentration n-layer 29 includes, for example, P as a group V atom.

The high-concentration p-layer 28 includes, for example, a p-type AlInAs layer or a p-type AlInGaAs layer including a p-type impurity with a higher concentration than the p-type impurity concentration included in the spacer layer 24. The p-type AlInGaAs layer or the p-type AlInGaAs layer includes, as the p-type impurity, the same impurity as the p-type impurity included in the spacer layer 24, for example. The high-concentration p-layer 28 has the p-type impurity concentration of, for example, 1×10¹⁹ to 1×10²⁰ cm⁻³. The high-concentration n-layer 29 includes the n-type InP including the n-type impurity having a higher concentration than the n-type impurity concentration included in the spacer layer 25. The n-type InP includes, as the n-type impurity, the same impurity as the n-type impurity included in the spacer layer 25, for example. The high-concentration n-layer 29 has the n-type impurity concentration of, for example, 1×10¹⁹ to 7×10¹⁹ cm⁻³.

### Manufacturing Method

Next, a description will be given of a manufacturing method of the surface-emitting laser 1 according to the present embodiment.

To manufacture the surface-emitting laser 1, a compound semiconductor is formed in bulk on, for example, the substrate 10 including InP, using, for example, an epitaxial crystal growth method such as MOCVD (Metal Organic Chemical Vapor Deposition: organic metal vapor deposition) method. At this time, as a raw material of the compound semiconductor, methyl-based organic metal gas such as trimethylaluminum (TMAI), trimethylgallium (TMGa), and trimethylindium (TMIn), phosphine (PH3) gas, and arsine (AsH₃) gas are used. As a raw material of donor impurities, for example, disilane (Si₂H₆) is used, and as a raw material of acceptor impurities, for example, carbon tetrabromide (CBr₄) is used.

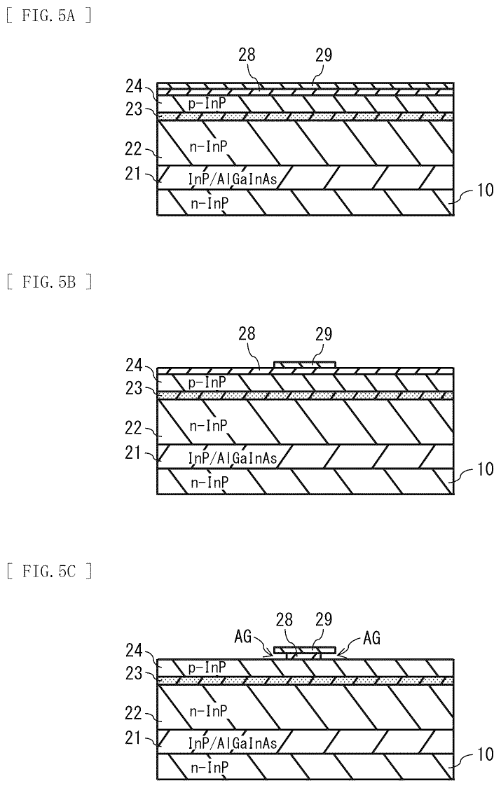

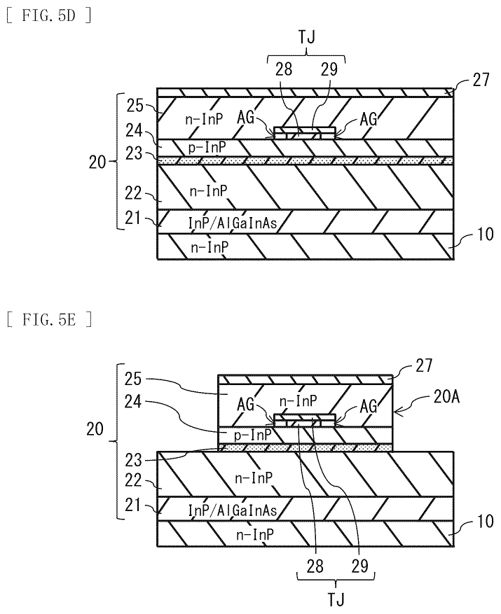

First, the semiconductor DBR layer 21, the spacer layer 22, the active layer 23, the spacer layer 24, the high-concentration p-layer 28, and the high-concentration n-layer 29 are formed on the substrate 10, using, for example, the epitaxial crystal growth method such as the MOCVD method (FIG. 5A). Next, for example, after a circular shaped resist layer (not illustrated) in plan view is formed, the high-concentration n-layer 29 is selectively etched by, for example, wet etching, with this resist layer as a mask. This forms the high-concentration n-layer 29 having a circular shape in plan view is formed (FIG. 5B). Subsequently, the high-concentration p-layer 28 is selectively etched, by, for example, he wet etching. At this time, the high-concentration p-layer 28 is over-etched. This forms the air gap AG on a side surface of the high-concentration p-layer 28 (FIG. 5C). Thereafter, the resist layer is removed.

Next, the spacer layer 25 and the contact layer 27 are formed on a surface including the surface of the circular high-concentration n-layer 29, using, for example, the epitaxial crystal growth method such as the MOCVD method (FIG. 5D). At this time, the air gap AG is being occluded due to mass transport. A degree of occlusion of the air gap AG varies depending on a temperature or a growth rate during regrowth. The higher the temperature is, the more the occlusion of the air gap AG progresses. Therefore, it is preferable to perform regrowth under process conditions that do not allow the occlusion of the air gap AG to progress excessively and the air gap AG itself to disappear.

Next, for example, a circular resist layer (not illustrated) is formed that covers a predetermined region centered on the circular high-concentration p-layer 28 and the high-concentration n-layer 29 in plan view. Then, with this resist layer as a mask, a semiconductor layer such as the contact layer 27 and the like is selectively etched and the semiconductor layer is etched to a depth that reaches the spacer layer 22. At this time, it is preferable to use, for example, RIE (Reactive Ion Etching) with CI-based gas. In this manner, the columnar mesa part 20A is formed (FIG. 5E). At this time, the spacer layer 22 is exposed on the foot of the mesa part 20A. That is, the exposed surface 22S is formed in the foot of the mesa part 20A. Then, the resist layer is removed.

Next, for example, the contact layer 27 having an annular shape is formed on the top surface of the mesa part 20A. Then, the electrode layer 32 having an annular shape and in contact with the top surface of the contact layer 27 is formed, and the electrode layer 31 is formed at a predetermined area of the exposed surface 22S (FIG. 1). Then, for example, the dielectric DBR layer 26 is formed, for example, at a central portion of the spacer layer 25 (a portion of the spacer layer 25 surrounded by the electrode layer 32) (FIG. 1). In this manner, the surface-emitting laser 1 is manufactured.

### Operation

In the surface-emitting laser 1 having such a configuration, in a case where a predetermined voltage is applied between the electrode layer 31 electrically coupled to the spacer layer 22 and the electrode layer 32 electrically coupled to the contact layer 27, electric currents constricted by the tunnel junction layer TJ including the high-concentration p-layer 28 and the high-concentration n-layer 29 are injected into the active layer 23. This results in light emission due to recombination of electrons and holes. At this time, light generated at the active layer 23 is confined by the tunnel junction layer TJ in the lamination in-plane direction. In particular, in the present embodiment, because the air gap AG having the refractive index of 1 exists on the side surface of the tunnel junction layer TJ, the light confinement in the lamination in-plane direction is effectively performed. As a result, the emitter 20 generates laser oscillation at the oscillation wavelength of λ0. Then, light leaking from the dielectric DBR layer 26 becomes beam-shaped laser light L and is output to outside from the light emitting surface 1S.

### Effects

Next, a description will be given of effects of the surface-emitting laser 1 according to the present embodiment.

In the present embodiment, the tunnel junction layer TJ is surrounded by the spacer layers 24 and 25 that are disposed between the active layer 23 and the dielectric DBR layer 26, and the air gap AG exists between a portion of the side surface of the tunnel junction layer TJ and the spacer layer 25. As a result, for example, even in a case where the As-based material is exposed on the side surface of the tunnel junction layer TJ, the air gap AG exists between such a surface and the spacer layer 25, so that there is no direct contact between such a surface and the spacer layer 25. Consequently, it is possible to reduce a risk that crystal faults occur in the spacer layer 25 due to the conditions of film formation. Therefore, even in a case where the tunnel junction structure is used, in the present embodiment, it is possible to provide the surface-emitting laser 1 where crystal faults are less likely to occur. In addition, it is possible to provide the surface-emitting laser 1 with good device characteristics.

In the present embodiment, the high-concentration p-layer 28 and the high-concentration n-layer 29 include respective materials having mutually different group V atoms. The high-concentration p-layer 28 includes, for example, As as a group V atom. The high-concentration n-layer 29 includes, for example, P as a group V atom. This allows the tunnel junction layer TJ to have a lower resistance and the tunnel junction layer TJ to be applied to InP-based devices.

In the present embodiment, the high-concentration p-layer 28 includes Al atoms. This makes it possible to improve the effect of taking in p-type impurities to the high-concentration p-layer 28 in the manufacturing process by an action of the Al atoms. As a result, it is possible to efficiently increase the p-type impurity concentration of the high-concentration p-layer 28.

In the present embodiment, the high-concentration p-layer 28 includes the p-type AlInAs layer or the p-type AlInGaAs layer, and the high-concentration n-layer 29 includes n-type InP. This makes it possible to narrow the bandgap of the high-concentration p-layer 28 while lattice-matching with the spacer layers 22, 24, and 25. As a result, it is possible to reduce the resistance of the tunnel junction layer TJ. This also allows for application of the tunnel junction layer TJ to the InP-based devices.

In the present embodiment, the semiconductor DBR layer 21 and the spacer layers 22, 24, and 25 include the InP-based semiconductors. This allows for excellent light emission characteristics to be provided in the 1.31 μm and the 1.5 μm bands that are the low loss regions of optical fibers.

In addition, in the present embodiment, the current path formed by the electrode layer 31 and the electrode layer 32 is provided not through the semiconductor DBR layer 21 and the dielectric DBR layer 26, so that it is not necessary to configure both of the semiconductor DBR layer 21 and the dielectric DBR layer 26 with semiconductors doped with impurities. As a result, it is possible to reduce loss due to free carrier absorption in the semiconductor DBR layer 21 and the dielectric DBR layer 26. Moreover, it is possible to reduce the impurity concentration of the spacer layer 22 itself, so that, in this respect, reduction in the loss due to the free carrier absorption in the spacer layer 22 is also possible. Therefore, it is possible to achieve high efficiency and low voltage.

In addition, in the present embodiment, the reduced loss due to the free carrier absorption makes it possible to increase the oscillation efficiency. Furthermore, reduction in an operating voltage makes it possible to reduce power consumption of the surface-emitting laser 1. In addition, it is possible to suppress the temperature rise of the surface-emitting laser 1 to a low level, thereby improving reliability of the surface-emitting laser 1. Furthermore, the reduced operating voltage allows arraying of the surface-emitting laser 1 to be realized.

In the present embodiment, the electrode layer 31 has the structure in which Ti, Pt, Au are stacked in this order from the exposed surface 22S side. Ti is in contact with the exposed surface 22S and is in ohmic contact with the exposed surface 22S. Pt prevents diffusion of impurities included in the spacer layer 22 into Au. Au improves bonding ability between the electrode layer 31 and a solder. This makes it possible to achieve a lower voltage.

In the present embodiment, the spacer layers 22, 24, and 25 include the InP-based semiconductors, the semiconductor DBR layer 21 includes the undoped InP-based semiconductors, and the dielectric DBR layer 26 includes dielectrics. This makes it possible to reduce the loss due to the free carrier absorption in the semiconductor DBR layer 21 and the dielectric DBR layer 26. Therefore, it is possible to achieve high efficiency.

In the present embodiment, the semiconductor DBR layer 21 and the dielectric DBR layer 26 are configured so that the laser light L is output from the DBR layer 26 side. This makes it possible to realize the top emitting type laser.

In the present embodiment, the mesa part 20A is provided. This allows the electrode layer 31 to be formed close to the tunnel junction layer. As a result, it is possible to achieve a lower voltage.

### 2. Modification Examples of First Embodiment

### Modification Example A

In the above-described embodiment, the air gap AG has an annular shape surrounding the entire side surface of the high-concentration p-layer 28. In the above-described embodiment, however, as illustrated in FIG. 6, for example, a plurality of the air gaps AGs, disposed side by side at a predetermined interval in plan view, may exist between the side surface of the high-concentration p-layer 28 and the spacer layer 25. Even in this case, it is possible to provide the surface-emitting laser 1 with a fewer crystal faults compared to a case in which no air gap AG is provided.

### Modification Example B

In the above-described embodiment and the modification example thereof, a cavity length of the surface-emitting laser 1 may be three or more times larger than the oscillation wavelength λ0 of the surface-emitting laser 1. It is made possible to make the cavity length of the surface-emitting laser 1 three or more times larger than the oscillation wavelength λ0 of the surface-emitting laser 1 in this manner, because the light confinement by the air gap AG in the lamination in-plane direction has been effectively performed. In a case where the cavity length of the surface-emitting laser 1 is made three or more times larger than the oscillation wavelength λ0 of the surface-emitting laser 1 in this manner, it is possible to place the semiconductor DBR layer 21 away from the active layer 23 even in a case where a mixed crystal-based material (InGaAsP and AlInGaAs) having a lower thermal conductivity (approximately one tenth) than InP is used for the semiconductor DBR layer 21. As a result, it is possible to improve thermal dissipation in the cavity layer.

### Modification Example C

In the above-described embodiment and the modification example thereof, for example, as illustrated in FIG. 8, a substrate 40 and a semiconductor DBR layer 41 may be provided instead of the substrate 10 and the semiconductor DBR layer 21.

The substrate 40 is a crystal growth substrate used to cause epitaxial crystal growth of the semiconductor DBR layer 41. In this modification example, it is possible to omit the substrate 40. The substrate 10 is an n-type GaAs substrate. The n-type GaAs substrate includes, for example, silicon (Si) and the like, as the n-type impurity. The semiconductor DBR layer 41 is, for example, a undoped GaAs-based semiconductor DBR layer. The semiconductor DBR layer 41 is configured by alternately stacking the low-refractive index semiconductor layers including undoped AlAs and the high-refractive index semiconductor layers including undoped GaAs. The low-refractive index semiconductor layers and the high-refractive index semiconductor layers each have the optical thickness of, for example, λ0×1/4.

In this modification example, the substrate 40 where the semiconductor DBR layer 41 is formed is bonded with a surface on the semiconductor DBR layer 41 side opposing the spacer layer 22. Therefore, in this modification example, an interface between the semiconductor DBR layer 41 and the spacer layer 22 is a junction surface 40A. Here, the semiconductor DBR layer 41 is not included in the current path. Therefore, it is possible to bond the semiconductor DBR layer 41 in accordance with a magnitude or an application of the oscillation wavelength λ0.

### Modification Example D

In the above-described embodiment and the modification example thereof, for example, as illustrated in FIG. 9, the tunnel junction layer TJ may be configured by stacking the high-concentration p-layer 28, a high-concentration n-layer 41, an n-layer 42, and an n-layer 43 in this order from the active layer 23 side. In this modification example as well, the air gap AG exists between the portion of the side surface of the tunnel junction layer TJ and the spacer layer 25.

The high-concentration p-layer 28 is in contact with a bottom surface of the high-concentration n-layer 41, and the n-layer 42 is in contact with a top surface of the high-concentration n-layer 41. The high-concentration n-layer 41 is in contact with a bottom surface of the n-layer 42 and the n-layer 43 is in contact with a top surface of the n-layer 42. The n-layer 42 is in contact with a bottom surface of the n-layer 43 and the spacer layer 25 is in contact with a top surface and a side surface of the n-layer 43. As illustrated in FIG. 9, for example, the air gap AG exists between the side surfaces of the high-concentration p-layer 28, the high-concentration n-layer 41, the n-layer 42, and the spacer layer 25. The air gap AG has an annular shape surrounding the side surfaces of the high-concentration p-layer 28, the high-concentration n-layer 41, and the n-layer 42. That is, the spacer layer 25 is not in contact with t the side surfaces of the high-concentration p-layer 28, the high-concentration n-layer 41, and the n-layer 42.

The high-concentration p-layer 28, the high-concentration n-layer 41, and the n-layer 42 include a material having a group V atom different from that of the n-layer 43, and the n-layer 43 includes a material having a group V atom different from that of the high-concentration p-layer 28, the high-concentration n-layer 41, and the n-layer 42. The high-concentration p-layer 28, the high-concentration n-layer 41, and the n-layer 42 each include, for example, As as a group V atom. The n-layer 43 includes, for example, P as a group V atom.

The high-concentration n-layer 41 includes, for example, an n-type AlInGaAs layer including an n-type impurity with a higher concentration than the n-type impurity concentration included in the spacer layer 25. The n-type InP includes, as the n-type impurity, the same impurity as the n-type impurity included in the spacer layer 25, for example. The high-concentration n-layer 29 has the n-type impurity concentration of, for example, 1×10¹⁹ to 6×10¹⁹ cm⁻³. The n-layer 42 includes the n-type AlInGaAs including the n-type impurity having a lower concentration than the n-type impurity concentration included in the high-concentration n-layer 41. The n-type InP includes, as the n-type impurity, the same impurity as the n-type impurity included in the spacer layer 25, for example. The n-layer 42 has the n-type impurity concentration of, for example, 1×10¹⁵ to 5×10¹⁸ cm⁻³. The n-layer 43 includes the n-type InP including the n-type impurity having a lower concentration than the n-type impurity concentration included in the high-concentration n-layer 41. The n-type InP includes, as the n-type impurity, the same impurity as the n-type impurity included in the spacer layer 25. The n-layer 43 has the n-type impurity concentration of, for example, 1×10¹⁸ to 5×10¹⁸ cm⁻³.

It is to be noted that in this modification example, the tunnel junction layer TJ is configured by stacking the high-concentration p-layer 28, the high-concentration n-layer 41, and the n-layer 43 in this order from the active layer 23 side, as illustrated in FIG. 10, for example. Even in this case, the air gap exists between the portion of the side surface of the tunnel junction layer TJ and the spacer layer 25.

In this case, the high-concentration p-layer 28 is in contact with the bottom surface of the high-concentration n-layer 41, and the n-layer 43 is in contact with the top surface of the high-concentration n-layer 41. The n-layer 41 is in contact with the bottom surface of the n-layer 43, and the spacer layer 25 is in contact with the top surface and side surface of the n-layer 43. As illustrated in FIG. 10, for example, the air gap AG exists between the side surfaces of the high-concentration p-layer 28 and the high-concentration n-layer 41 and the spacer layer 25. The air gap AG has an annular shape surrounding the entire side surfaces of the high-concentration p-layer 28 and the n-layer 41. That is, the spacer layer 25 is not in contact with the side surfaces of the high-concentration p-layer 28 and the n-layer 41.

As such, in this modification example, the tunnel junction layer TJ is a laminate having two or more layers including Al and As as a group V atom. In such a case, it is possible to adjust size of the air gap AG (in particular, a length in the stacking direction) by adjusting the number of stacks. This makes it possible to adjust the light emission characteristics by adjusting the number of stacks. It is to be noted that no deterioration was observed in the tunnel junction layer TJ in the reliability test, even in a case where the tunnel junction layer is a laminate having two or more layers including Al and As as a group V atom.

### Modification Example E

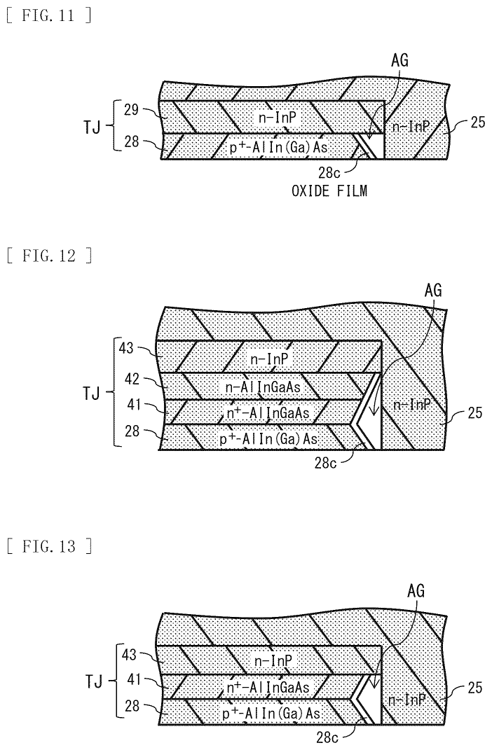

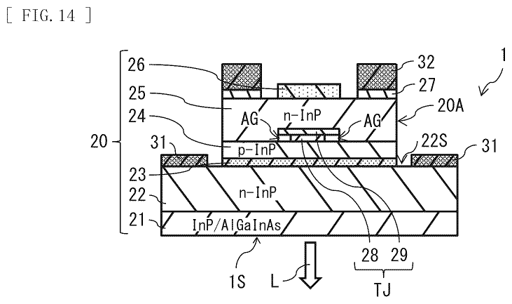

In the above-described embodiment and the modification example thereof, for example, as illustrated in FIG. 11, FIG. 12, and FIG. 13, for example, an oxide film 28c may be provided in contact with an area opposing the air gap AG on the side surface of the tunnel junction layer TJ. The oxide film 28c is an amorphous oxide film, and is, for example, an Al₂O₃ film. The oxide film 28c is formed in the manufacturing process by the side surface of the layer including Al of the side surfaces of the tunnel junction layer TJ coming into contact with a gas including oxygen (for example, the atmosphere). Formation of the oxide film 28c on the side surface of the tunnel junction layer TJ makes it possible to suppress occlusion of the air gap AG due to the mass transport and to form a stable air gap structure.

It is to be noted that the oxide film 28c has the refractive index that is an intermediate value between the refractive index of the air gap AG and the refractive index of the tunnel junction layer TJ. Therefore, in the stacked surface including the air gap AG, the oxide film 28c serves as a layer with the graded refractive index. This results in a modest change in the refractive index on the side surface of the tunnel junction layer TJ as compared to the above-described embodiments. Therefore, it is possible to adjust the light confinement by adjusting a thickness of the oxide film 28c.

### Modification Example F

In the above-described embodiment and the modification example thereof, the surface-emitting laser 1 may be a back emitting type laser having the light emitting surface IS provided on the back surface. In this modification example, the surface-emitting laser 1 may be configured so that the laser light L having the oscillation wavelength λ0 is output from the semiconductor DBR layer 21 side, as illustrated in FIG. 14, for example. Specifically, in the emitter 20, the number of pairs and the reflective index of the reflecting mirror on the semiconductor DBR layer 21 side and the number of pairs and the reflective index of the reflecting mirror on the dielectric DBR layer 26 side are configured so that the laser light L having the oscillation wavelength λ0 is output from the semiconductor DBR layer 21 side. Even in such a configuration, it is possible to obtain the similar effects to the above-described embodiment and the modification example thereof.

### 3. Second Embodiment

### Configuration

A description will be given of a surface-emitting laser 2 according to the second embodiment of the present disclosure. FIG. 15 illustrates a cross-sectional configuration example of the surface-emitting laser 2. FIG. 16 illustrates a plan configuration example of the surface-emitting laser 2.

In the present embodiment, a groove section 20B is provided instead of the mesa part 20A in the above-described first embodiment and the modification examples. The exposed surface 22S is formed on a bottom surface of the groove section 20B. Even in such a configuration, it is possible to obtain the similar effects to the above-described first embodiment and the modification examples thereof.

### 4. Modification Example of Second Embodiment

### Modification Example G

In the above-described second embodiment, the surface-emitting laser 2 may be the back emitting type laser having the light emitting surface IS provided on the back surface. In this modification example, the surface-emitting laser 2 may be configured so that the laser light L having the oscillation wavelength λ0 is output from the semiconductor DBR layer 21 side, as illustrated in FIG. 17, for example. Even in such a configuration, it is possible to obtain the similar effects to the above-described second embodiment and the modification example thereof.

### 5. Third Embodiment

### Configuration

A description will be given of a surface-emitting laser array 3 according to the third embodiment of the present disclosure. FIG. 18 illustrates a cross-sectional configuration example of the surface-emitting laser array 3. The surface-emitting laser array 3 is configured to include a plurality of the emitters 20 according to the above-described first embodiment and the modification examples. The surface-emitting laser array 3 includes the plurality of emitters 20 on the common substrate 10.

The plurality of emitters 20 is provided on the one mesa part 20A, and each of the emitters 20 is the top emitting type laser having the light emitting surface 1S provided on the top surface of the mesa part 20A. The semiconductor DBR layer 21, the spacer layer 22, the active layer 23, and the spacer layers 24 and 25 are shared by the emitters 20, and the dielectric DBR layer 26 is provided separately in each of the emitters 20.

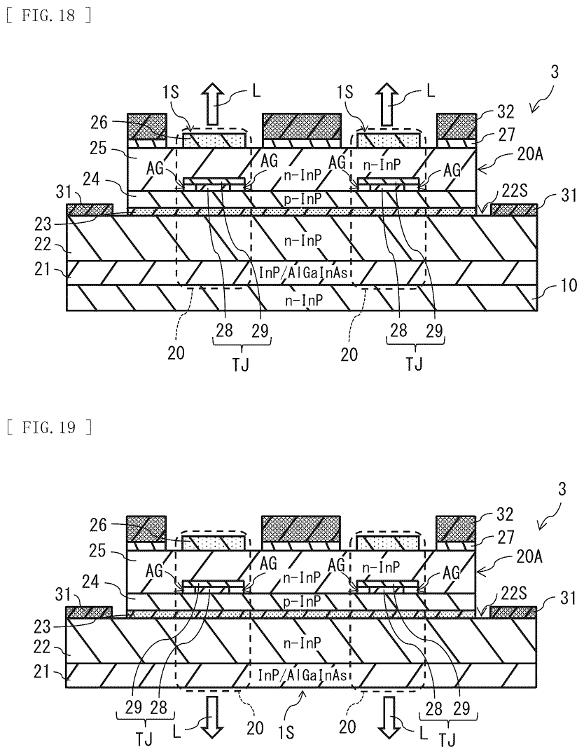

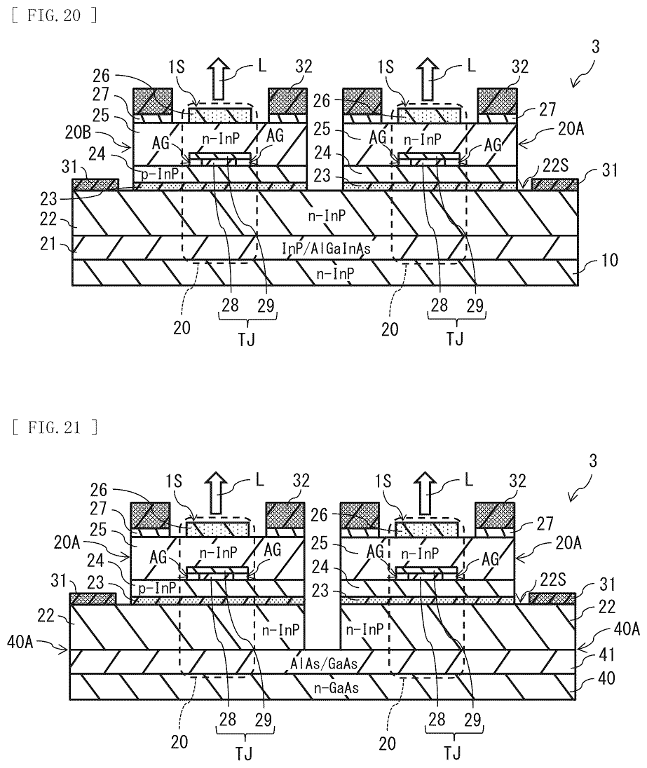

It is to be noted that in the present embodiment, the surface-emitting laser array 3 may be the back emitting type laser having the light emitting surface IS provided on the back surface, as illustrated in FIG. 19, for example. In addition, in the present embodiment, the semiconductor DBR layer 21 and the spacer layer 22 may be shared by the emitters 20, and the active layer 23, the spacer layers 24 and 25, and the dielectric DBR layer 26 may be provided separately in each of the emitters 20, as illustrated in FIG. 20, for example.

In addition, in the present embodiment, in each of the emitters 20, the spacer layer 22, the active layer 23, the spacer layers 24 and 25, and the dielectric DBR layer 26 may be provided separately from each other, as illustrated in FIG. 21, for example. At this time, as illustrated in FIG. 21, for example, the substrate 40 and the semiconductor DBR layer 41 may be provided instead of the substrate 10 and the semiconductor DBR layer 21. At this time, the semiconductor DBR layer 21 is shared by the emitters 20. In addition, in each of the emitters 20, the spacer layer 22 and the semiconductor DBR layer 41 of the emitter 20 are bonded to each other with the spacer layer 22 opposing the semiconductor DBR layer 41. Therefore, in tis case, an interface between the spacer layer 22 of each of the emitters 20 and the semiconductor DBR layer 41 is the junction surface 40A.

In addition, in the present embodiment, the substrate 40 and the semiconductor DBR layer 41 may be provided instead of the substrate 10 and the semiconductor DBR layer 21. In addition, in the present embodiment, the groove section 20B may be provided instead of the mesa part 20A.

In either case, it is possible to obtain the similar effects to the above-described first and second embodiments and the modification examples thereof.

As described above, the present disclosure has been described by citing the embodiments and the modification examples thereof. However, the present disclosure is not limited to the above-described embodiments and the like, and various modifications are possible. It is to be noted that the effects described herein are merely exemplary. The effects of the present disclosure are not to be limited to the effects described herein. The present disclosure may have effects other than the effects described herein.

In addition, for example, the present disclosure may also be configured as follows.
(1)

A surface-emitting laser including:
a first DBR (Distributed Bragg Reflector) layer;
a second DBR layer;
an active layer disposed between the first DBR layer and the second DBR layer;
a first spacer layer disposed between the active layer and the first DBR layer;
a second spacer layer disposed between the active layer and the second DBR layer; and
a tunnel junction layer disposed between the active layer and the second DBR layer, and surrounded by the second spacer layer, in which
the second spacer layer and a portion of a side surface of the tunnel junction layer have an air gap therebetween.
(2)

The surface-emitting laser according to (1), further including an amorphous oxide film in contact with an area, on the side surface of the tunnel junction layer, opposing the air gap.
(3)

The surface-emitting laser according to (1) or (2), in which
the tunnel junction layer includes a semiconductor layer of a first conductivity type and a semiconductor layer of a second conductivity type that are stacked in this order from a side of the active layer, and
the semiconductor layer of the first conductivity type and the semiconductor layer of the second conductivity type include respective materials including mutually different group V atoms.
(4)

The surface-emitting laser according to (3), in which, of the semiconductor layer of the first conductivity type and the semiconductor layer of the second conductivity type, at least the semiconductor layer of the first conductivity type includes an Al atom.
(5)

The surface-emitting laser according to (3), in which
the semiconductor layer of the first conductivity type includes an AlInAs layer or an AlInGaAs layer, and
the semiconductor layer of the second conductivity type includes an InP layer.
(6)

The surface-emitting laser according to (3), in which
the semiconductor layer of the first conductivity type includes an AlInAs layer or an AlInGaAs layer, and
the semiconductor layer of the second conductivity type includes an AlInGaAs layer and an InP layer that are stacked in this order from a side of the semiconductor layer of the first conductivity type.
(7)

The surface-emitting laser according to any one of (1) to (6), in which the second spacer layer and at least a portion of the side surface of the tunnel junction layer have a plurality of air gaps therebetween, the plurality of air gaps being disposed side by side at a predetermined interval in plan view.
(8)

The surface-emitting laser according to any one of (1) to (7), in which the first DBR layer, the first spacer layer, and the second spacer layer include an InP-based semiconductor.
(9)

The surface-emitting laser according to any one of (1) to (7), in which
the first spacer layer and the second spacer layer include an InP-based semiconductor, and
the first DBR layer and the first spacer layer are bonded to each other.
(10)

The surface-emitting laser according to (9), in which the first DBR layer includes a GaAs-based semiconductor DBR layer.
(11)

The surface-emitting laser according to any one of (1) to (10), in which the surface-emitting laser has a cavity length three or more times larger than an oscillation wavelength of the surface-emitting laser.
(12)

A surface-emitting laser array including a plurality of emitters provided on a common semiconductor substrate, each of the emitters including
a first DBR (Distributed Bragg Reflector) layer,
a second DBR layer,
an active layer disposed between the first DBR layer and the second DBR layer,
a first spacer layer disposed between the active layer and the first DBR layer,
a second spacer layer disposed between the active layer and the second DBR layer, and
a tunnel junction layer disposed between the active layer and the second DBR layer, and surrounded by the second spacer layer, in which
the second spacer layer and a portion of a side surface of the tunnel junction layer have an air gap therebetween.
(13)

The surface-emitting laser array according to (12), in which
the first DBR layer and the first spacer layer are shared by the emitters,
the active layer, the second spacer layer, and the second DBR layer are provided separately in each of the emitters, and
the semiconductor substrate includes a crystal growth substrate on which the first DBR layer and the first spacer layer of each of the emitters are formed through epitaxial crystal growth.
(14)

The surface-emitting laser array according to (12), in which
the first DBR layer is shared by the emitters,
the first spacer layer, the active layer, the second spacer layer, and the second DBR layer are provided separately in each of the emitters, and
the first DBR layer and the first spacer layer are bonded to each other.

In the surface-emitting laser according to one embodiment of the present disclosure, the tunnel junction layer is surrounded by the second spacer layer disposed between the active layer and the second DBR layer, and the air gap exists between the portion of the side surface of the tunnel junction layer and the second spacer layer. As a result, for example, even in a case where the As-based material is exposed on the side surface of the tunnel junction layer, the air gap exists between such a surface and the second spacer layer, so that there is no direct contact between such a surface and the second spacer layer. Consequently, it is possible to reduce the risk that crystal faults occur in the second spacer layer due to the conditions of film formation. Therefore, in the present disclosure, even in a case where the tunnel junction structure is used, it is possible to provide the surface-emitting laser and the surface-emitting laser array where crystal faults are less likely to occur.

The present application claims the benefit of Japanese Priority Patent Application JP2023-039022 filed with the Japan Patent Office on Mar. 13, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A surface-emitting laser comprising:
a first DBR (Distributed Bragg Reflector) layer;
a second DBR layer;
an active layer disposed between the first DBR layer and the second DBR layer;
a first spacer layer disposed between the active layer and the first DBR layer;
a second spacer layer disposed between the active layer and the second DBR layer; and
a tunnel junction layer disposed between the active layer and the second DBR layer, and surrounded by the second spacer layer, wherein
the second spacer layer and a portion of a side surface of the tunnel junction layer have an air gap therebetween.

2. The surface-emitting laser according to claim 1, further comprising an amorphous oxide film in contact with an area, on the side surface of the tunnel junction layer, opposing the air gap.

3. The surface-emitting laser according to claim 1, wherein
the tunnel junction layer includes a semiconductor layer of a first conductivity type and a semiconductor layer of a second conductivity type that are stacked in this order from a side of the active layer, and
the semiconductor layer of the first conductivity type and the semiconductor layer of the second conductivity type include respective materials including mutually different group V atoms.

4. The surface-emitting laser according to claim 3, wherein, of the semiconductor layer of the first conductivity type and the semiconductor layer of the second conductivity type, at least the semiconductor layer of the first conductivity type includes an Al atom.

5. The surface-emitting laser according to claim 3, wherein
the semiconductor layer of the first conductivity type comprises an AlInAs layer or an AlInGaAs layer, and
the semiconductor layer of the second conductivity type comprises an InP layer.

6. The surface-emitting laser according to claim 3, wherein
the semiconductor layer of the first conductivity type comprises an AlInAs layer or an AlInGaAs layer, and
the semiconductor layer of the second conductivity type includes an AlInGaAs layer and an InP layer that are stacked in this order from a side of the semiconductor layer of the first conductivity type.

7. The surface-emitting laser according to claim 1, wherein the second spacer layer and at least a portion of the side surface of the tunnel junction layer have a plurality of air gaps therebetween, the plurality of air gaps being disposed side by side at a predetermined interval in plan view.

8. The surface-emitting laser according to claim 1, wherein the first DBR layer, the first spacer layer, and the second spacer layer include an InP-based semiconductor.

9. The surface-emitting laser according to claim 1, wherein
the first spacer layer and the second spacer layer include an InP-based semiconductor, and
the first DBR layer and the first spacer layer are bonded to each other.

10. The surface-emitting laser according to claim 9, wherein the first DBR layer comprises a GaAs-based semiconductor DBR layer.

11. The surface-emitting laser according to claim 1, wherein the surface-emitting laser has a cavity length three or more times larger than an oscillation wavelength of the surface-emitting laser.

12. A surface-emitting laser array comprising a plurality of emitters provided on a common semiconductor substrate, each of the emitters including
a first DBR (Distributed Bragg Reflector) layer,
a second DBR layer,
an active layer disposed between the first DBR layer and the second DBR layer,
a first spacer layer disposed between the active layer and the first DBR layer,
a second spacer layer disposed between the active layer and the second DBR layer, and
a tunnel junction layer disposed between the active layer and the second DBR layer, and surrounded by the second spacer layer, wherein
the second spacer layer and a portion of a side surface of the tunnel junction layer have an air gap therebetween.

13. The surface-emitting laser array according to claim 12, wherein
the first DBR layer and the first spacer layer are shared by the emitters,
the active layer, the second spacer layer, and the second DBR layer are provided separately in each of the emitters, and
the semiconductor substrate comprises a crystal growth substrate on which the first DBR layer and the first spacer layer of each of the emitters are formed through epitaxial crystal growth.

14. The surface-emitting laser array according to claim 12, wherein
the first DBR layer is shared by the emitters,
the first spacer layer, the active layer, the second spacer layer, and the second DBR layer are provided separately in each of the emitters, and
the first DBR layer and the first spacer layer are bonded to each other.
